(19) United States
(12) Patent Application Publication
(10) Pub. No.: US 2005/0109606 A1
(43) Pub. Date: May 26, 2005

(54) Composite barrier films and method

(76) Inventors: Xiao-Ming He, Arcadia, CA (US); Ramin Heydarpour, Beverly Hills, CA (US); Ali R. Mehrabi, Los Angeles, CA (US); Jay R. Akhave, Claremont, CA (US)

Correspondence Address: Armand P. Boisselle;RENNER, OTTO, BOISSELLE & SKLAR, LLP, 19th Floor, 1621 Euclid Avenue, Cleveland, OH, 44115, US

(21) Appl. No.: 10/969,836

(22) Filed: Oct. 21, 2004

Related U.S. Application Data
(62) Division of application No. 10/325,575, filed on Dec. 20, 2002.

(51) Int. Cl. C23C 14/32

(52) U.S. Cl. 204/192.14; 204/192.15

(57) ABSTRACT

In one embodiment, the invention relates to a method of depositing a silicon nitride based coating on a plastic substrate to form a composite barrier film which comprises depositing a silicon nitride based coating on the substrate by sputtering of a silicon target in an atmosphere comprising at least about 75% by volume nitrogen. In another embodiment, the composite films prepared by the method of the invention comprise a silicon nitride based coating on a flexible plastic substrate wherein the silicon nitride based coating has a thickness of less than about 220 nm and a visible light transmittance of at least about 75%.

### CROSS REFERENCE TO RELATED APPLICATION

This application is a division of copending U.S. application Ser. No. 10/325,575 filed on Dec. 20, 2002. The disclosure of application Ser. No. 10/325,575 is hereby incorporated by reference in its entirety.

### TECHNICAL FIELD OF THE INVENTION

The present invention relates generally to composite barrier films comprising a silicon nitride based coating, and more particularly, to such composite films which having improved barrier and optical characteristics.

### BACKGROUND OF THE INVENTION

Many different types of products and devices are environmentally sensitive. More particularly, there are many different devices and products which are sensitive to gases and liquids which can cause deterioration of the product or device, and, eventually, render the product or device useless. Such products include food, pharmaceuticals, health and beauty aids, electronics, medical devices and display devices. Barrier coatings have been included in the packaging of such products to protect them from environmental gases and liquids, such as oxygen, water vapor in the atmosphere, or chemicals used in the processing, handling, storage and use of the products. A number of packaging applications, such as baked goods, electronics, pharmaceuticals, toothpaste, etc., require relatively low Oxygen Transmission Rate (“OTR”) of approximately less than 5 cc/m²/day and/or a Moisture Vapor Transmission Rate (“MVTR”) of approximately less than 0.5 g/m²/day.

Plastic films are often used in product packaging, but the gas and liquid permeation resistance of the plastic films used are not always sufficient to provide the desired level of protection. Also, certain display devices, such as liquid crystal displays (LCDs), light-emitting devices (LEDs) and light-emitting polymers (LEPs) require packaging that has very low OTR and MVTR. In order to improve the barrier characteristics of generally available plastics, coatings have been applied to plastic substrates to decrease the gas and liquid permeability. For example, opaque, metallized plastic films have been used, and although these films are relatively inexpensive, they are not transparent. As an alternative, transparent SiOx-coated plastic films may sometimes be used, but the cost of SiOx-coated plastic films is often too high for many commercial applications. Plastic films which are vacuum-coated with other inorganic materials, such as aluminum, AlOₓ, SiOₓN_{y} and Si₃N₄ also have been suggested as reducing the oxygen permeability and water vapor permeability of plastic films.

### SUMMARY OF THE INVENTION

In one embodiment, the invention relates to composite films having barrier properties, and more particularly, to composite films which comprise a silicon nitride based coating on a flexible plastic substrate wherein the silicon nitride based coating has a thickness of up to about 220 nm and is deposited on the plastic substrate by sputtering of a silicon target in an atmosphere comprising at least 75% by volume of nitrogen. The composite barrier film has a visible light transmittance of at least about 75%.

In another embodiment, the invention relates to a method of depositing a silicon nitride based coating on a plastic substrate to form a composite barrier film which comprises depositing a silicon nitride based coating on the substrate by sputtering of a silicon target in an atmosphere comprising at least about 75% by volume nitrogen.

The composite films of the invention exhibit desirable oxygen and/or water barrier characteristics, and highly transparent composite films can be prepared in accordance with the method of the present invention. In one embodiment, the composite films of the invention also are characterized as having one or more of the following desirable properties: high clarity, low haze, high surface smoothness, good flexibility, low water contact angle, and improved interfacial adhesion.

### DESCRIPTION OF THE INVENTION

The term “transparent” when referring to one or more layers of coating of the composite films means that any visible material beneath such layers can be seen through such layers. The barrier films of the present invention have a visible light transmission of at least 75% as determined with an ultraviolet/visible spectrometer (UV/VIS).

The term “clear” when referring to one or more layers are to the composite films of the invention means that the clarity of the layers of the composite films is at least about 95 percent, and the layers of composite film have a haze of less than about 10 percent. Clarity is measured in accordance with TAPPI Test T425 os, and haze is measured in accordance with ASTM Test Method D-1003.

In one embodiment, the present invention relates to a method of preparing a composite barrier film comprising depositing a silicon nitride based coating having a thickness of up to about 250 nm on at least one surface of a plastic substrate having an upper surface and a lower surface by sputtering of a silicon target in an atmosphere comprising at least about 75% by volume of nitrogen, wherein the surface of the plastic substrate on which the silicon nitride based coating is deposited has root-mean-square (RMS) roughness of about 5 nm or less, and the composite has a visible light transmittance of at least about 75%.

The method of the invention provides a silicon nitride based coating that also is characterized as being a relatively smooth coating (low RMS roughness) containing a minimum of defects such as pin holes and cracks, and the silicon nitride based coating exhibits good adhesion to the plastic substrate (inter layer adhesion). As discussed more fully below, these advantageous properties can be further improved in some embodiments by depositing a polymer film layer over the substrate before depositing the silicon nitride based layer. This polymer film layer may be referred to as an under layer or planarizing layer. The polymer reduces the roughness of the substrate layer and thereby improves the characteristics of the silicon nitride based layer deposited on the polymer coated substrate by reducing the density, sizes and shapes of defects in the silicon nitride based layer.

The sputtering techniques or processes used in the present invention include sputtering techniques known in the art. Such techniques include magnetron sputtering, ion beam sputtering, ion beam enhanced or assisted deposition, laser ablation deposition, etc. In one embodiment, the magnetron sputtering process utilized in the method of the present invention can be a DC or RF magnetron sputtering procedure. In one embodiment, the deposition procedure is DC magnetron sputtering. The sputtering of a silicon target to deposit the desired silicon nitride based coating on the plastic substrate can be conducted using standard commercially available sputtering equipment.

The silicon nitride based coating is formed by sputtering of a silicon target in an atmosphere comprising at least about 75% by volume of nitrogen. In one embodiment, the atmosphere comprises a mixture of nitrogen and argon comprising at least 75% by volume of nitrogen. In another embodiment, the atmosphere is free of hydrogen. In yet another embodiment, the atmosphere comprises a mixture of nitrogen and argon containing at least about 80% by volume of nitrogen, and the atmosphere is free of hydrogen.

The silicon targets utilized in the sputtering process of the present invention generally contain at least about 99% silicon. In one embodiment, the silicon target comprises at least 99.5% silicon. The thickness of the silicon nitride based coating is generally up to about 250 nm. In one embodiment, the thickness of the silicon nitride based coating is from about 5 to about 220 nm. In some embodiments, a thickness greater than about 220 nm can be deposited, but it has been found that deposits of 220 nm or less provide adequate barrier properties. The thickness of the silicon nitride based coating on the substrate and/or the deposition rate can be controlled by the amount of sputtering power, the concentration of the nitrogen in the atmosphere, and, in a continuous process, and described more fully below, the line speed. For example, the deposition rate can be increased by increasing the sputtering power or decreasing the line speed and/or the nitrogen/argon ratio. However, as the amount of argon increases, there is a tendency for the coating to develop a yellow coloring.

The silicon nitride based coatings obtained by the method of the invention are dense. In one embodiment, the silicon nitride based coating is amorphous in structure. The silicon nitride based coatings contain some oxygen (from about 3 to about 25 atomic percent) and some carbon (from about 2 to about 15 atomic percent). In one embodiment the amorphous silicon nitride based coatings have atomic ratios of Si/N of about 1.1 to 1.5, and O/N of from about 0.2 to 0.6. Since no oxygen is added to the atmosphere of the sputtering process, it is believed that the oxygen is derived from residual oxygen in the equipment and from oxygen absorbed from the atmosphere when the composite films are removed from the sputtering equipment. The carbon is believed to be derived mainly from surface contamination. Accordingly, the silicon nitride based coating which is obtained of the process of the invention may be characterized as a silicon nitride based SiCON film. In one embodiment, silicon nitride based films can be formed with lower atomic ratios of Si/N and O/N, and lower carbon content, by increasing the N₂/Ar ratio and the sputtering power.

The plastic substrates which can be coated with the silicon nitride based coatings as described herein may include a variety of self-supporting plastic films, more particularly, flexible self-supporting plastic films that can support the thin silicon nitride based coating. The term “plastic” is utilized to refer to high polymers, usually made from polymer synthetic resins, which may be combined with other ingredients, such as curatives, fillers, reinforcing agents, tolerance, plasticizers, etc. The plastic films may be prepared from thermoplastic materials and thermosetting materials.

The flexible plastic films should have a sufficient thickness and mechanical integrity so as to be self-supporting. In one embodiment, however, the film should not be so thick as to be rigid. In one embodiment, the flexible plastic substrate is the thickest layer of the composite film, and the thickness of the flexible substrate may be, for example up to about 200 micron (8 mils). Consequently, the substrate determines to a large extent, the mechanical and thermal stability of the fully structured composite film.

It is also desirable that the plastic substrates have smooth surfaces since the roughness of the substrate surface will have an effect on the roughness and other properties of the silicon nitride based coating. Thus, in one embodiment, the RMS roughness of the surface of the plastic substrates is no greater than 5 nm. In another embodiment, the RMS roughness of the surface of the plastic substrate is no greater than 4 or even no greater than 3 nm.

Another characteristic of the flexible plastic substrate material in one embodiment is the Tg of the material. Tg is defined as a glass transition temperature at which plastic material will change from a glassy state to the rubbery state. It may comprise a range before the material may actually flow. Suitable materials for the plastic substrate include thermoplastics of a relatively low glass transition temperature (up to about 150° C.), as well as materials of a higher glass transition temperature (above about 150° C.). The choice of material for the plastic substrate will depend on factors such as manufacturing process conditions (e.g., deposition temperature, and annealing temperature, etc.) as well as the post-manufacturing conditions (e.g., in a process line of a displays manufacturer). Some of the plastic substrates discussed below can withstand higher processing temperatures of up to at least about 200° C. and in some instances up to 300° C.-350° C. without damage. Thus, in one embodiment, the plastic substrate utilized in the method in composite films of the present invention is a polyester, polyethersulfone (PES), polycarbonate (PC), polysulfone, phenolic resin, epoxy resin, polyimide, polyetherester, polyetheramide, cellulose acetate, aliphatic polyurethane, polyacrylonitrile, polyfluorocarbon, poly(meth)acrylate, aliphatic or cyclic polyolefin, or mixtures thereof.

Examples of useful polyesters include polyethylene terephthalate (PET), polyethylene naphthalate (PEN), etc. Examples of polyolefin prepared from aliphatic polyolefins include high density polyethylene (HDPE), low density polyethylene (LDPE), polypropylene, copolymers of propylene with other alpha-olefins such as ethylene and butylene, oriented polypropylene (OPP), etc.

Examples of commercially available cyclic polyolefins include: Arton™ made by Japan Synthetic Rubber Company, Tokyo, Japan; Zeanor™ made by Zeon Chemicals L.P., Tokyo, Japan; and Topas™ made by Celanese A.G., Kronberg, Germany. Arton is a poly(bis(cyclopentadiene)) condensate wherein the cyclopentadiene group contains an attached polar group.

In one embodiment, the plastic substrate can be reinforced with a polymer coating that is referred to in the industry as a hard coating (HC) before the silicon nitride based coating is deposited thereon. Such hard coatings may typically have a thickness from about 1 micron to about 50 microns, and the coating may be provided by free radical polymerization (initiated either thermally or by ultraviolet radiation) of an appropriate polymerizable material. Depending on the substrate, different hard coatings can be used. For example, when the substrate is a polyester such as Arton, a particularly useful hard coating is the coating known as “Lintec.” Lintec contains UV-cured polyester acrylate and colloidal silica, and when deposited on Arton, it has a surface composition of 35 atom percent carbon, 45 atom percent oxygen and 20 atom percent silica, excluding hydrogen. Another particularly useful hard coating is the acrylic coating sold under the trademark “Terrapin” by Tekra Corporation, New Berlin, Wis. It has been observed that in some embodiments, the hard coating provides significant improvement in certain properties of the composite film such as improved interfacial adhesion between the silicon nitride based film and the plastic substrate, and a reduction in roughness of the composite film. That is, the hard coating may serve as a planarizing layer. The use of the hard coating also may result in an improvement in the surface morphology of the composite film. In another embodiment, when the composite film is laser etched to form electrodes, the hard coating may facilitate the etching process. The characteristics and properties of a variety of commercially available suitable plastic substrates are summarized in the following Table I.

TABLE I
Properties of Commercial Plastic Substrates

| Plastics | | | | | HC/Arton | HC/PET |
|---|---|---|---|---|---|---|
| for deposition | Arton | PET | PET | PET | Lintec | Autotype |
| Source/ | JSR | Dupont Teijin | GE | DH | CHC-PN188W | AutoFlex |
| Grade | G-7810 | Film, ST-505 | | | PFW | EBA180L |
| Thickness (μm) | 188 | 175 | 175 | 175 | 188 | 180 |
| Surface RMS (nm) | 3.7 | 5.2 | 2.7 | 3.8 | 2.3 | Not tested. |
| Tg (C.) | 171 | 78 | ˜78 | ˜78 | 171 | 78 |
| MVTR | 35.1 | 3.41 | 2.82 | 2.73 | 31.4 | 3.5 |
| (g/m²/day) | (40/100) | (40/100) | (35/90) | (35/90) | (40/100) | (35/90) |
| (° C./RH) | | | | | | |
| OTR | 1060 | 10.4 | 11.1 | 11.1 | 163 | 13.8 |
| (cc/m²/day) | (35/90) | (35/90) | (35/90) | (35/90) | (35/90) | (35/90) |
| (° C./RH) | | | | | | |
| Surface energy | 38.9 | 43.3 | NA | NA | 36.3 | 40.4-42.0 |
| (mN/M) | | | | | | |
| % Transmittance | 91.31 | 92.75 | >90 | >85 | 91.14 | 89 |
| (@ 550 nm) | | | | | | |

In some embodiments, the method of the present invention may further comprise a pre-deposition purging step. This step comprises purging the surface of the plastic substrate with a plasma prior to deposition of the silicon nitride based film. The plasma may be argon or a mixture of argon and nitrogen. Plasmas of other gases can also be used. The use of a pre-deposition plasma step can improve interlayer adhesion of the composite film according to the present invention.

As mentioned above, it has been discovered that the characteristics of the silicon nitride based coating can be improved when the silicon nitride based coating is deposited on a substrate surface which has an RMS roughness of about 5 nm or less. In one embodiment, the RMS roughness of the surface upon which the silicon nitride based coating is deposited is less than 4 nm or even less than 3 nm. When the surface of the plastic substrate exceeds the above roughnesses, it is possible and desirable to coat the plastic substrate with a coating which has been referred to as a smoothing or planarizing coating which has the effect of reducing the surface roughness of the plastic substrate prior to application of the silicon nitride based coating. In one embodiment, the hard coatings described previously may function as a planarizing layer since the coatings generally reduce the roughness of the surface of the hard coated plastic substrate. In another embodiment, polyacrylate coatings are useful as the planarizing layer. In one embodiment, UV curable acrylate formulations are useful in depositing an acrylate planarizing layer on plastic substrates. A particular example of an acrylate which can be polymerized by UV curing is pentaerythritol triacrylate. The acrylate coatings may typically have a thickness of from about 1 micron to about 50 microns. More often, the thickness of the planarizing layer may be from about 1 to about 10 microns.

The acrylate monomers which can be polymerized by UV curing include mono-, di-, tri- and tetraacrylates. Examples of useful acrylate monomers include 2-phenoxy ethyl acrylate, lauryl acrylate, hexane diol diacrylate (HDDA), tripropylene glycol diacrylate (TRPGDA), diethylene glycol diacrylate, neopentyl glycol diacrylate, triethylene glycol diacrylate, trimethylol propane triacrylate, ethoxylated trimethylol propane triacrylate, pentaerythritol triacrylate, etc.

The following formulation is an example of a UV curable acrylate formulation useful in depositing an acrylate planarizing coating on the plastic substrates described above.

Acrylate Formulation

| Material | % by wt. |
|---|---|
| Pentaerythritol triacetate | 79.907 |
| Irgacure 907 | 1.980 |
| Tinuvin 292 | 0.694 |
| Tinuvin 1130 | 0.694 |
| Butyl acetate | 16.726 |

Irgacure 907 is 2-methyl-1-[4-(methylthio)phenyl]-2-(4-morphodinyl-1)-1-propanone. Tinuvin 292 is a mixture of bis-(1,2,2,6,6-pentamethyl-4-piperidinyl) sebacate; methyl-(1,2,2,6,6-pentamethyl-4-piperidinyl) sebacate; and dimethyl sebacate. Tinuvin 1130 comprises poly(oxy-1,2-ethanediyl), alpha-[3-[3-[2H-benzotriazole-2-yl]-5-(1,1-dimethylethyl)-4 hydroxyphenyl]-1-oxypropyl]-omega-[3-[3[(2H-benzotriazole-2-yl]-5-(1,1-dimethylethyl-4-hydroxylphenyl)-1-oxopropoxy].

In other embodiments, the method of the present invention may further comprise a post-deposition annealing step. Typically, the post-deposition annealing step comprises annealing the silicon nitride based coating in air at a temperature of between about 125° C. and about 175° C. for a period from 0.5 to 3 hours. The temperature of the annealing process is limited and determined by the properties of the components of the composite film. Certain appearance properties of the composite film such as color and brightness are considered when establishing suitable annealing conditions. The use of a post-deposition annealing step can improve interfacial adhesion of the composite films of the invention.

The method of the present invention may be conducted on a continuous or semi-continuous basis (i.e., roll-to-roll deposition), or the method can be conducted on a batch process. Thus, the method of the present invention may be a continuous or semi-continuous process for forming a composite barrier film which comprises
(A) providing a moving continuous sheet of flexible plastic substrate having an upper surface and a lower surface;
(B) depositing a silicon nitride based coating continuously on at least one surface of the flexible plastic substrate by sputtering of a silicon target in an atmosphere comprising at least about 75% by volume of nitrogen to form a composite film wherein the thickness of the silicon nitride based coating is from about 10 to about 220 nm and the surface of the plastic substrate on which the silicon nitride based coating is deposited has a RMS roughness of less than about 5 nm; and
(C) collecting the composite film in a continuous roll wherein the composite barrier film has a visible light transmittance of at least about 75%.
   The line speed of the roll of plastic material may be adjusted to control the thickness of the silicon nitride based layer deposited on the substrate. The line speed also can be adjusted to be optimum for the target size used and for the scale of the deposition process. For example, a higher line speed results in a thinner coating whereas a slower speed results in a thicker coating.

The composite barrier films of the present invention which comprise a plastic substrate coated with a silicon nitride based coating film wherein the coating has been deposited using sputtering of a silicon target in an atmosphere comprising at least 75% by volume of nitrogen as described above are characterized as having one or more of the following desirable properties: good barrier properties as evidenced by low MVTR and/or low OTR; high optical transmission; high clarity; low haze; good surface smoothness; low water content water contact angle; good flexibility; and good interfacial adhesion of the films.

The following examples illustrate the preparation of continuous roll composite barrier films of the present invention utilizing a DC magnetron sputtering process. The base pressure of the deposition chamber is 1.5 to 4×10⁻⁶ mT, and the working or deposition pressure is 2.4 to 3.1 mT. A silicon target of 99.999% purity is sputtered with a power of 400 to 2000 watts for deposition of the silicon nitride based films. During the depositions, the nitrogen and argon contents of the atmosphere are varied as indicated. No hydrogen is added to the atmosphere. In addition, the line speed of the plastic roll is adjusted from 0.1 to 2.0 feet/min to control the thickness or growth rate of the amorphous silicon nitride based films. The distance between the plastics and the target is 10 inches for the depositions.

Table II summarizes examples illustrating the preparation of composite films of the invention based on a HC/Arton substrate. Table III summarizes examples illustrating the preparation of composite films of the invention based on GE PET and autotype HC/PET substrates where the N₂/Ar flow ratio is 8:2 and the sputtering power is 1500 W for all examples.

TABLE II
Composite Films Based on HC/Arton

| | N₂/Ar | Sputtering | SiN Thickness |
|---|---|---|---|
| Example | Flow Ratio | Power (W) | (nm) |
| 1 | 10/0 | 1200 | 25.24 |
| 2 | 8/2 | 1500 | 37.5 |
| 3 | 10/0 | 1200 | 33.31 |
| 4 | 8/2 | 1500 | 41.52 |
| 5 | 8/2 | 1500 | 135.4 |
| 6 | 8/2 | 1500 | 42.4 |
| 7 | 8/2 | 1500 | 77.7 |
| 8 | 8/2 | 1500 | 100.7 |
| 9 | 8/2 | 1500 | 120.3 |
| 10 | 8/2 | 1000 | 125.6 |
| 11 | 8/2 | 1500 | 219.5 |
| 12 | 8/2 | 1200 | 24.4 |
| 13 | 8/2 | 1200 | 12.4 |
| 14 | 8/2 | 1200 | 20.0 |
| 15 | 8/2 | 2000 | 61.44 |
| 16 | 8/2 | 1000 | 19.7 |
| 17 | 8/2 | 1200 | 27.36 |
| 18 | 7/2 | 1500 | 127.53 |
| 19 | 8/2 | 1500 | 88.45 |
| 20 | 6/2 | 1000 | 75.88 |
| 21 | 7/2 | 1200 | 69.79 |
| 22 | 7/2 | 800 | 45.46 |
| 23 | 6/2 | 600 | 48.88 |
| 24 | 8/2 | 2000 | 100.06 |
| 25 | 8/2 | 1500 | 23.77 |
| 26 | 8/2 | 1500 | 10.27 |

TABLE III
Composite Films Based on PET

| Example | Substrate | SiN Thickness (nm) |
|---|---|---|
| 27 | GE PET | 37.5 |
| 28 | GE PET | 42.4 |
| 29 | GE PET | 77.7 |
| 30 | GE PET | 120.3 |
| 31 | GE PET | 125.6 |
| 32 | GE PET | 135.4 |
| 33 | GE PET | 219.5 |
| 34 | HC/PET | 37.5 |
| 35 | HC/PET | 42.4 |
| 36 | HC/PET | 77.7 |
| 37 | HC/PET | 125.6 |
| 38 | HC/PET | 135.4 |

Some of the characteristics and properties of the composite barrier films prepared in accordance with the present invention and illustrated in Examples 1-38 have been determined and are summarized below. The thickness of the films were measured with an Ellipsometer. The chemical composition of the silicon nitride based coating was determined with XPS spectrum whereas the surface morphology and roughness were determined using an atomic force microscope (AFM), a screen electric microscope (SEM) and optical microscopy. The visible light transmittance of the films was determined with an ultra-violet/visible spectrometer (UV/VIS). The barrier properties were measured using samples 4 inch×4 inch in size. A surface area of 50.00 cm² of each of the samples was analyzed by the PERMATRAN-W 3/31 (MG) instrument to determine the MVTR by ASTM Method F1249, and by the OX-TRAN 2/20 (ML System) instrument to determine the OTR by ASTM Method F1927. These instruments are operated at 35° C. and 90% relative humidity. In the measurement of MVTR, a nitrogen flow of 10 sccm is used to carry the water vapor, while an oxygen flow of 20 sccm is used as the permeant in the OTR measurement.

The interfacial adhesion of the films is evaluated using a 180° peel test method with 3M tape 810 on cross hatched samples as described more fully below.

When the samples are post-annealed, the annealing process is in air with a temperature of under 150° C. for a period of 120 minutes.

The following Table IV summarizes the chemical composition of some of the silicon nitride based films deposited in the above examples. Before analysis, the sample surface is sputter etched with Ar⁺ for 2 minutes to remove the surface contamination except for Example 6 which is sputter etched for 6 minutes.

TABLE IV
Composition of SiN Films
The surfaces of the composite films are
smooth and flat when observed by AFM.

| Composite | Atomic % | | | | Atomic Ratio | |
|---|---|---|---|---|---|---|
| of Example | C | N | O | Si | Si/N | O/N |
| 1 | 12.6 | 31.0 | 18.4 | 38.0 | 1.23 | 0.59 |
| 3 | 7.0 | 36.9 | 14.1 | 42.0 | 1.14 | 0.38 |
| 5 | 5.8 | 38.9 | 12.5 | 42.8 | 1.10 | 0.32 |
| 6 | 3.9 | 38.1 | 13.3 | 44.7 | 1.17 | 0.35 |
| 12 | 7.8 | 36.8 | 14.9 | 40.5 | 1.10 | 0.41 |

The roughness of the HC/Arton surface and the roughness of the surface of the silicon nitride based films of some of the Examples was determined and is reported in the following Table V. The scan size is 20 microns. As can be seen from the results in Table V, the deposition of the silicon nitride based film improves the surface smoothness of the HC/Arton substrate (control). Increasing thickness of the silicon nitride based film does not appear to have an influence on the RMS roughness of the composite.

TABLE V
Surface Roughness of SiN Barrier Films

| | | RMS | |
|---|---|---|---|
| Composite | | Composite | |
| of | SiN Surface | Surface | |
| Example | Thickness (nm) | (nm) | R max (nm) |
| Control | 0 | 2.3 | NA |
| 17 | 12.4 | 1.07 | 16 |
| 14 | 20.0 | 1.1 | 26 |
| 12 | 24.4 | 1.3 | 20 |
| 2 | 37.5 | 1.2 | 19 |
| 6 | 42.4 | 1.1 | 14 |
| 7 | 77.7 | 1.1 | 24 |
| 9 | 120.3 | 1.1 | 17 |
| 11 | 219.5 | 1.2 | 22 |

The silicon nitride based films and the composite films of the present invention are useful as environmental barriers for various products and devices such as foods, electronics, optics, pharmaceuticals, etc. In particular, the composite films of the invention are effective as barriers against oxygen and/or water vapor permeation. In some embodiments, the MVTR can be reduced to below 0.5 g/m²/day and the OTR can be reduced to a level below 5 or below 1.5 cc/m²/day at 35° C. and 90° relative humidity, depending in part on the barrier properties and smoothness of the substrate. In other embodiments of the invention, the MVTR and/or the OTR of the composite films can be reduced to 0.005 g/m²/day and 0.005 cc/m²/day or lower, respectively, at 35% C and 90% relative humidity.

The results shown in Tables VI and VII illustrate the barrier properties of some of the composite films of the invention when measured at 35° C. and 90% relative humidity.

TABLE VI
Barrier Properties (HC/Arton Substrate)

| Example | SiN Thickness (nm) | MVTR g/m²/day | OTR cc/m²/day |
|---|---|---|---|
| Control | 0 | 31.4* | 163 |
| 1 | 25.24 | <0.005 | 1.13 |
| 2 | 37.5 | <0.005 | <0.005 |
| 3 | 33.31 | <0.005 | <0.005 |
| 4 | 41.52 | <0.005 | <0.005 |
| 5 | 135.4 | <0.005 | <0.005 |
| 6 | 42.4 | <0.005 | <0.005 |
| 7 | 77.7 | <0.005 | <0.005 |
| 8 | 100.7 | <0.005 | 0.96 |
| 9 | 120.3 | <0.005 | <0.005 |
| 10 | 125.6 | <0.005 | <0.005 |
| 11 | 219.5 | <0.005 | <0.005 |
| 12 | 24.44 | <0.005 | 0.69 |
| 13 | 12.40 | <0.005 | 1.59 |
| 15 | 61.44 | <0.005 | <0.005 |
| 16 | 19.7 | <0.005 | 0.005 |

*at 40° C. and 100% relative humidity

TABLE VII
Barrier Properties (PET Substrate)

| | | SiN | MVTR | |
|---|---|---|---|---|
| Example | Substrate | Thickness (nm) | g/m²/day | OTR cc/m²/day |
| Control | GE PTE | 0 | 2.82 | 11.1 |
| 27 | GE PTE | 37.5 | 0.09 | 0.53 |
| 28 | GE PTE | 42.4 | 0.16 | 0.35 |
| 29 | GE PTE | 77.7 | 0.05 | 0.51 |
| 30 | GE PTE | 120.3 | 0.07 | 1.75 |
| 31 | GE PTE | 125.6 | 0.11 | 0.40 |
| 32 | GE PTE | 135.4 | <0.005 | 0.19 |
| 33 | GE PTE | 219.5 | 0.04 | 0.45 |
| Control | HC/PTE | 0 | 3.5 | 13.8 |
| 34 | HC/PTE | 37.5 | 0.44 | 1.43 |
| 35 | HC/PTE | 42.4 | 0.49 | 1.10 |
| 36 | HC/PTE | 77.7 | 0.26 | 0.50 |
| 37 | HC/PTE | 125.6 | 0.18 | 1.00 |
| 38 | HC/PTE | 135.4 | 0.25 | 1.05 |

The composite films of the invention also are characterized as having desirable optical properties such as high optical transmittance and clarity and low haze. In one embodiment, the films have a visible light transmittance of at least about 75% (generally measured at 550 nm). In another embodiment the visible light transmittance may be at least about 80%, 85%, 90%, or even at least about 95%. In addition, when the silicon nitride based films are deposited on clear plastic substances, such as HC/Arton and PET, the composite films have low haze values (e.g., less than 1.0, and more often less than 0.50) and high clarity (e.g., above 95% and even above 99%). The results of optical measurements on some of the silicon nitride coated substrates are summarized in the following Table VIII.

TABLE VIII
Optical Properties

| Composite Film | Substrate | SiN Film | T % @ | | Clarity |
|---|---|---|---|---|---|
| of Example | Type | Thickness (nm) | 550 nm | Haze | % |
| Control | HC/Arton | 0 | 91.14 | NA | NA |
| 5 | HC/Arton | 135.4 | 97.5 | 0.31 | 99.8 |
| 7 | HC/Arton | 77.7 | 85.5 | 0.72 | 99.6 |
| 8 | HC/Arton | 100.7 | 91.9 | 0.36 | 99.9 |
| 10 | HC/Arton | 125.6 | 98.3 | 0.39 | 99.8 |
| 12 | HC/Arton | 24.44 | 95.83 | 0.27 | 99.7 |
| Control | GE PET | 0 | 92.75 | 1.45 | 99.15 |
| 1 | GE PET | 25.34 | 98.81 | 1.54 | 99.2 |
| 29 | GE PET | 77.7 | 88.0 | 1.55 | 99.5 |
| 31 | GE PET | 125.6 | 96.1 | 1.72 | 99.6 |
| 32 | GE PET | 135.4 | 94.8 | 1.23 | 99.7 |

The hydrohobic properties of the substrate films also are improved when the substrates are coated with the silicon nitride based films of this invention. In particular, the contact angle of water to GE PET is reduced when the GE PET is coated with silicon nitride based films in accordance with the present invention. A summary of the measurements of the contact angle of water for GE PET and for silicon nitride base film coated GE PET is found in the following Table IX. A reduction in the contact angle suggests an increase in surface energy of the plastic material after deposition of the silicon nitride based films.

TABLE IX
Contact Angles of Water

| Example | SiN Film Thickness (nm) | 8_{wca} (degree) |
|---|---|---|
| Control | 0 | 64.0 |
| 1 | 25.34 | 24.5 |
| 29 | 77.7 | 27.0 |
| 31 | 125.6 | 35.0 |
| 32 | 135.4 | 31.5 |

The interfacial adhesion properties of the silicon nitride based coatings to the plastic substrate also have been determined for the composite barrier film of several of the above Examples using a 180° peel test. Samples (3 in.×1 in.) of the composite films of the Examples listed in the following table were cross-hatched in the usual manner, and 3M tape 810 is laminated to the surface using a 4.5 lb. roller. The tape is kept on the sample for a 20-hr dwell time. The gauge length is 1 inch, and the cross head speed is 12 in/min. The average peel force is determined and the results are shown in the following table. The surface characteristics of the silicon nitride base coatings after cross-hatching and after completion of the 180° peel test are also observed for damage. Minimum damage is a good indication of good interfacial adhesion.

TABLE X
Interfacial Adhesion Test Results

| | | | Surface situation | | |
|---|---|---|---|---|---|
| | Film | Peel | As deposited | After 180° peel test | |
| | thickness | Force | and Cross- | | Cross-hatched + Tape |
| Example | (nm) | (g) | hatched | Tape 810 | 810 |
| 15 | 61.44 | 437.18 | No observable | No observable | No observable |
| | | | damage | damage | damage |
| 18 | 127.53 | 288.25 | Cross-hatched: | Same as | Cracks and flakes |
| | | | cracks formed | above | along the cut lines |
| | | | along the cut | | |
| | | | lines | | |
| 19 | 88.45 | 337.21 | Same as above | Same as | Same as above 18 |
| | | | 18 | above | |
| 20 | 75.88 | 325.69 | Cross-hatched: | Same as | Some cracks and |
| | | | some cracks | above | flakes formed |
| | | | formed along | | along the cut lines |
| | | | the cut lines | | |
| 21 | 69.79 | 350.37 | Cross-hatched: | Same as | Some cracks and |
| | | | some cracks | above | flakes formed |
| | | | formed along | | along the cut lines |
| | | | the cut lines | | |
| 22 | 45.46 | 380.56 | Cross-hatched: | Same as | Few smaller |
| | | | fewer fine | above | cracks formed |
| | | | cracks | | along the cut line |
| 23 | 48.88 | 322.42 | No observable | Same as | No observable |
| | | | damage | above | damage |
| 24 | 100.06 | 434.42 | Cross-hatched: | Same as | Cracks and flakes |
| | | | cracks formed | above | along the cut lines |
| | | | along the cut | | |
| | | | lines | | |
| 25 | 23.77 | 383.52 | No observable | Same as | No observable |
| | | | damage | above | damage |
| 26 | 10.27 | 371.08 | No observable | Same as | No observable |
| | | | damage | above | damage |

It has also been observed that in one embodiment, the composite films of the invention exhibit good flexibility properties, particularly when the thickness of the silicon nitride based coating is less than 100 nm and even less than 50 nm. That is, the composite films of the invention can be subjected to a flexibility test without significant damage to the interfacial adhesion of the silicone nitride based film to the plastic substrate. Little or no surface cracks or defects are observed after the flexibility test, and the composite films still exhibit very low OTR. Flexible composite films are desirable when the composite films are to be used as barriers for flexible displays.

While the invention has been explained in relation to its various embodiments, it is to be understood that other modifications thereof will become apparent to those skilled in the art upon reading the specification. Therefore, it is to be understood that the invention disclosed herein is intended to cover such modifications as fall within the scope of the appended claims.

1. A method of preparing a composite barrier film comprising depositing a silicon nitride based coating having a thickness of up to about 250 nm on at least one surface of a plastic substrate having an upper surface and a lower surface by sputtering of a silicon target in an atmosphere comprising at least about 75% by volume of nitrogen, wherein the surface of the plastic substrate on which the silicon nitride based coating is deposited has an RMS roughness of about 5 nm or less, and the composite has a visible light transmittance of at least about 75%.

2. The method of claim 1 wherein the atmosphere comprises a mixture of nitrogen and argon, and the mixture is free of hydrogen.

3. The method of claim 1 wherein the silicon nitride based coating is an amorphous coating.

4. The method of claim 1 wherein the thickness of the coating is from about 10 to about 220 nm.

5. The method of claim 1 wherein the sputtering is D.C. magnetron sputtering.

6. The method of claim 1 wherein the atmosphere comprises a mixture of nitrogen and argon containing at least about 80% nitrogen, and the mixture is free of hydrogen.

7. The method of claim 1 wherein RMS roughness of the surface of the plastic substrate on which the silicon nitride based coating is deposited is about 3 nm or less.

8. The method of claim 1 wherein the plastic substrate comprises a plastic layer and a polymeric planarizing layer wherein the planarizing layer has an RMS surface roughness of about 3 nm or less.

9. The method of claim 1 wherein the silicon nitride based coating contains oxygen, and the oxygen to nitrogen atomic ratio in the coating is less than about 1:1.

10. The method of claim 1 wherein the silicon nitride based coating contains from about 3 to about 25 atomic percent of oxygen.

11. The method of claim 1 wherein the silicon nitride based coating contains from about 2 to about 15 atomic percent of carbon.

12. The method of claim 1 wherein the silicon nitride base coating has an atomic ratio of silicon/nitrogen of from about 1.1 to about 1.5:1.

13. The method of claim 1 wherein the silicon nitride base coating has an atomic ratio of oxygen/nitrogen of from about 0.2:1 to about 0.6:1.

14. The method of claim 1 wherein the silicon nitride based coating contains carbon, and the carbon content is less than about 15 at %.

15. The method of claim 8 wherein the planarizing layer comprises an acrylic coating.

16. The method of claim 1 wherein the composite has a visible light transmittance of at least about 90%.

17. The method of claim 1 wherein the composite film has a clarity of at least about 99% and a haze of no greater than about 1.5%.

18. The method of claim 1 wherein the silicon nitride based coating has a water contact angle of no greater than about 36′.

19. The method of claim 1 wherein the composite barrier film has a moisture barrier transmission rate of less than about 0.005 g/m²/day and an oxygen transmission rate of less than 0.005 cc/m²/day, at conditions of 35° C. and 90% relative humidity.

20. The method of claim 1 wherein the silicon nitride based coating has sufficient interfacial adhesion to the remainder of the composite barrier to avoid delamination under a 180′ peel adhesion test.

21. The method of claim 1 wherein the plastic substrate comprises a polyester, polyethersulfone, polycarbonate, polysulfone, phenolic resin, epoxy resin, polyimide, polyetherester, polyetheramide, cellulose acetate, aliphatic polyurethane, polyacrylonitrile, polyfluorocarbon, poly(meth)acrylate, aliphatic or cyclic polyolefin, or mixtures of two or more thereof.

22. The method of claim 1 wherein the plastic substrate comprises a cyclic polyolefin.

23. The method of claim 1 wherein the plastic substrate comprises a polyester.

24. A method of forming a composite barrier film comprising:
(A) providing a moving continuous sheet of flexible plastic substrate having an upper surface and a lower surface;
(B) depositing a silicon nitride based coating continuously on at least one surface of the flexible plastic substrate by sputtering of a silicon target in an atmosphere comprising at least about 75% by volume of nitrogen to form a composite film wherein the thickness of the silicon nitride based coating is from about 10 to about 220 nm and the surface of the plastic substrate on which the silicon nitride based coating is deposited has a RMS roughness of less than about 5 nm; and
(C) collecting the composite film in a continuous roll wherein the composite barrier film has a visible light transmittance of at least about 75%.

25. The method of claim 24 wherein the atmosphere comprises a mixture of nitrogen and argon, and the mixture is free of hydrogen.

26. The method of claim 24 wherein the silicon nitride based coating is an amorphous coating.

27. The method of claim 24 wherein the sputtering is D.C. magnetron sputtering.

28. The method of claim 24 wherein the atmosphere comprises a mixture of nitrogen and argon containing at least about 80% nitrogen, and the mixture is free of hydrogen.

29. The method of claim 24 wherein RMS roughness of the surface of the plastic substrate on which the silicon nitride based coating is deposited is about 3 nm or less.

30. The method of claim 24 wherein the plastic substrate comprises a polyester, polyethersulfone, polycarbonate, polysulfone, phenolic resin, epoxy resin, polyimide, polyetherester, polyetheramide, cellulose acetate, aliphatic polyurethane, polyacrylonitrile, polyfluorocarbon, poly(meth)acrylate, aliphatic or cyclic polyolefin, or mixtures of two or more thereof.

31. The method of claim 24 wherein the plastic substrate comprises a cyclic polyolefin.

32. The method of claim 24 wherein the plastic substrate comprises a polyester.

33. The method of claim 24 wherein the silicon nitride based coating contains oxygen, and the oxygen to nitrogen atomic ratio in the coating is less than about 1:1.

34. The method of claim 24 wherein the silicon nitride based coating contains carbon, and the carbon content is less than about 15 at %.

35. The method of claim 24 wherein the plastic substrate comprises a plastic layer and a polymeric planarizing layer wherein the planarizing layer has an RMS surface roughness of about 3 nm or less.

36. The method of claim 35 wherein the planarizing layer comprises an acrylic coating.

37. The method of claim 24 wherein the composite has a visible light transmittance of at least about 90%.

38. The method of claim 24 wherein the composite film has a clarity of at least about 99% and a haze of no greater than about 1.5%.

39. The method of claim 24 wherein the silicon nitride based coating has a water contact angle of no greater than about 36°.

40. The method of claim 24 wherein the composite barrier film has a moisture barrier transmission rate of less than about 0.005 g/m²/day and an oxygen transmission rate of less than 0.005 cc/m²/day, at conditions of 35° C. and 90% relative humidity.

41. The method of claim 24 wherein the silicon nitride based coating has sufficient interfacial adhesion to the remainder of the composite barrier to avoid delamination under a 180° peel adhesion test.
